(19) United States
(12) Patent Application Publication
(10) Pub. No.: US 2021/0388846 A1
(43) Pub. Date: Dec. 16, 2021

(54) FAN BLADE STRUCTURE

(71) Applicant: Tung-Mao WANG, Taoyuan City (TW)

(72) Inventor: Tung-Mao WANG, Taoyuan City (TW)

(21) Appl. No.: 17/329,635

(22) Filed: May 25, 2021

(30) Foreign Application Priority Data
Jun. 12, 2020 (TW) 109207406

(51) Int. Cl. F04D 29/38

(52) U.S. Cl. CPC F04D 29/384; H05K 7/20136

(57) ABSTRACT

A fan blade structure comprises primarily an axle seat and plural vanes. Each vane is connected to the axle seat and includes a vane body. The vane body is provided an air pressure structure which is extended from the axle seat, and an air flow structure which is extended from an end of the air pressure structure. The angle of air pressure structure is smaller than that of air flow structure. By the air pressure structure, turbulent air can be pushed to a farther distance. On the other hand, as the tilt angle of air flow structure is larger than the angle of air pressure structure, the range of push to the turbulent aft can be increased, so as to improve the heat dissipation effect.

### BACKGROUND OF THE INVENTION

### a) Field of the Invention

The present invention relates to a fan, and more particularly to a fan blade structure.

### b) Description of the Prior Art

As the continuous progress of technology of electronic equipment, the requirement to the heat dissipation of equipment itself becomes higher and higher. In most of existing technology, an electronic element is cooled down by a fan; whereas an existing fan blade element includes an axle seat and plural vanes, with each vane being primarily a single plane structure or a single curved structure. When the fan blade element rotates, the air flow is guided out through the vanes. However, for the vanes in the single plane design or the single curved design, the range of heat dissipation is insufficient and not powerful enough when the air flow guided out; therefore, the heat dissipation effect cannot be improved.

### SUMMARY OF THE INVENTION

A primary object of the present invention is to provide a fan blade structure. With the design that the angle of an air pressure structure is smaller than that of an air flow structure, turbulent air can be pushed to a farther distance by the air pressure structure. In addition, the range of push to the turbulent air can be increased as the tilt angle of air flow structure is larger than the angle of air pressure structure, thereby increasing the range of push to the turbulent air, so as to improve the heat dissipation effect.

To achieve the abovementioned object, the present invention discloses a fan blade structure, comprising an axle seat and plural vanes. Each vane is connected to the axle seat and includes a vane body. The vane body is provided with an air pressure structure which is extended from the axle seat, and an air flow structure which is extended from an end of the air pressure structure, with that the angle of air pressure structure is smaller than that of air flow structure.

According to an embodiment of the present invention, the air pressure structure is provided with a downward pressure surface, and the pressure surface is a curved structure.

According to an embodiment of the present invention, the air flow structure is provided with a downward wind surface, and the wind surface is a curved structure.

According to an embodiment of the present invention, the axle seat is provided with a horizontal plane, and a first angle is defined between the horizontal plane and the air pressure structure.

According to an embodiment of the present invention, a second angle is defined between the air flow structure and the horizontal plane, and the second angle is larger than the first angle.

According to an embodiment of the present invention, the air pressure structure and the air flow structure are a continuous curved structure.

According to the abovementioned structures, the angle of air pressure structure is smaller than that of aft flow structure. Therefore, the air pressure structure can push turbulent air to a farther distance; whereas, as the tilt angle of air flow structure is larger than the angle of air pressure structure, the range of push to the turbulent air can be increased, thereby improving the heat dissipation effect.

It is worth mentioning that the pressure surface in the air pressure structure and the wind surface in the air flow structure are all a continuous curved structure, Therefore, when the fan blade structure rotates, the heat dissipation effect is increased and the best stability can be achieved.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a three-dimensional schematic view of a preferred embodiment of the present invention.

FIG. 2 shows a side view of the preferred embodiment of the present invention.

FIG. 3 shows a schematic view of angles of an air pressure structure and an air flow structure, according to the present invention.

FIG. 4 shows a schematic view of direction of air flow, according to the preferred embodiment of the present invention.

### DETAILED DESCRIPTION OF THE PREFERRED EMBODIMENTS

The structure, ratio, size, etc. shown in the accompanying drawings in this specification are only used associatively with the content disclosed in this specification, for the comprehension by those who are familiar with this technique. They are not to be used to limit the implementation of the present invention, and thus, do not have any physical meaning in terms of the technique. Any modification in structure, change in ratio or adjustment in size, should be still within the range covered in the technical content disclosed by the present invention, without affecting the efficacy and object achieved by the present invention. Meanwhile, the word employed in this specification, such as “one,” “two,” or “upper” is only for the convenience in description, and is not used to limit the range of implementation of the present invention. The change or adjustment in its relative relation should also be deemed as in the range of implementation of the present invention, without physically changing the technical content.

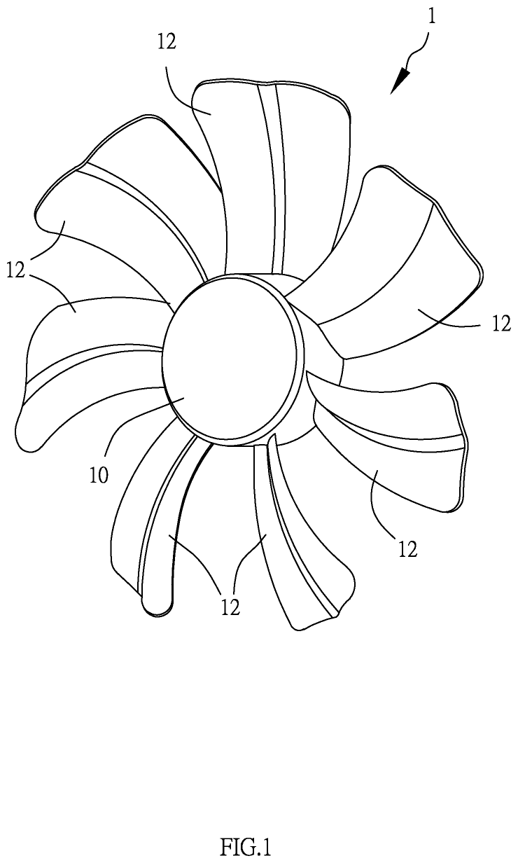

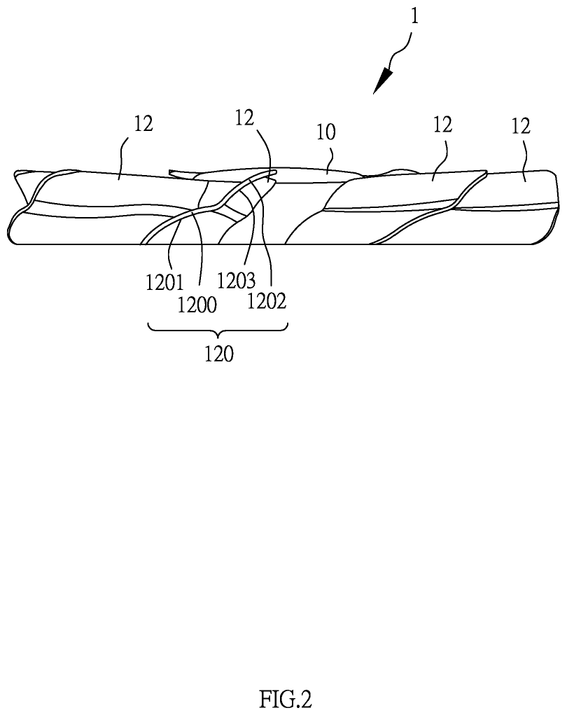

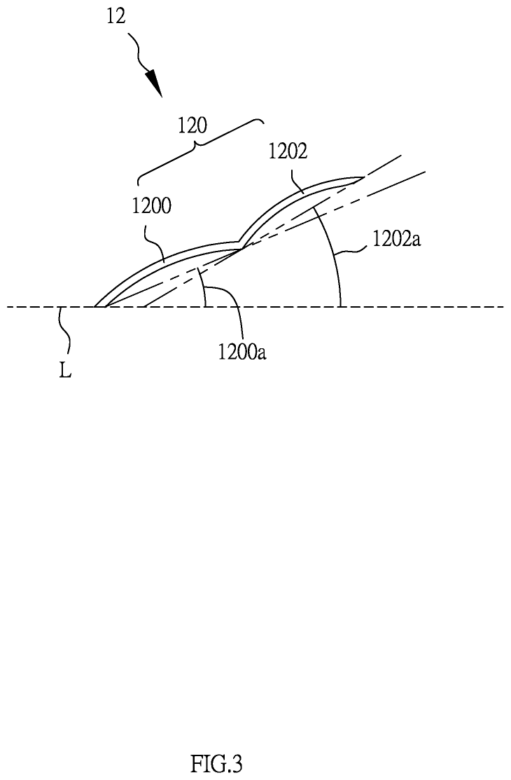

Referring to FIG. 1, FIG. 2 and FIG. 3, it shows a three-dimensional schematic view, a side view and a schematic view of angles of an air pressure structure and an air flow structure, according to a preferred embodiment of the present invention. The present invention discloses a fan blade structure 1, comprising primarily an axle seat 10 and plural vanes 12. Each vane 12 is connected to the axle seat 10 and includes a vane body 120. The vane body 120 is provided with an air pressure structure 1200 which is extended from the axle seat 10, and an air flow structure 1202 which is extended from an end of the air pressure structure 1200. The angle of air pressure structure 1200 is smaller than that of air flow structure 1202.

The abovementioned air pressure structure 1200 is provided with a downward pressure surface 1201, and the pressure surface 1201 is defined as a curved structure, In addition, the air flow structure 1202 is provided with a downward wind surface 1203, and the wind surface 1203 is defined as a curved structure.

The abovementioned axle seat 10 is provided with a horizontal plane L. A first angle 1200a is defined between the horizontal plane L and the air pressure structure 1200; whereas, a second angle 1202a is defined between the air flow structure 1202 and the horizontal plane L, and the second angle 1202a is larger than the first angle 1200a. On the other hand, the air pressure structure 1200 and the air flow structure 1202 are a continuous curved structure.

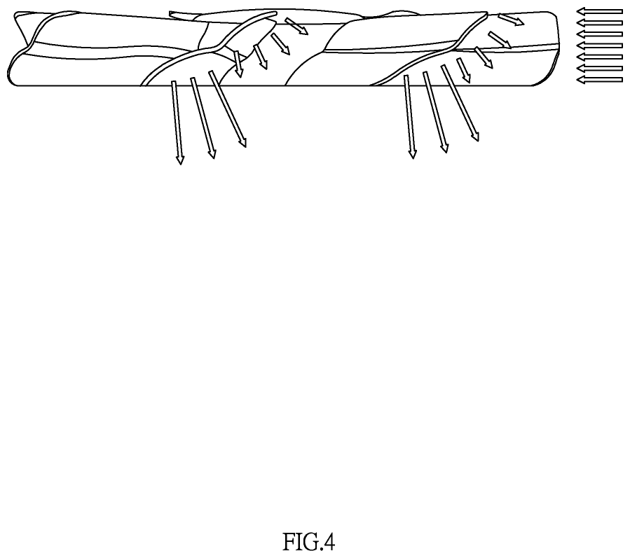

Referring to FIG. 4, it shows a schematic view of direction of air flow, according to the preferred embodiment of the present invention. The arrows show the direction of air flow, and the arrows face toward the air entrance of the fan blade structure 1. As the air pressure structure 1200 is connected to the axle seat 10, and the first angle 1200a between the air pressure structure 1200 and the horizontal plane L is smaller than the second angle 1202a between the air flow structure 1202 and the horizontal plane L, the air flow can be reduced to increase the transfer distance of air flow. In addition, as the second angle 1202a is larger than the first angle 1200a, after air enters into the fan blade structure 1, the air flow can be blown farther by the reflection of air flow structure 1202. It is worth mentioning that the pressure surface 1201 in the air pressure structure 1200 and the wind surface 1203 in the air flow structure 1202 are all a continuous curved structure; therefore, when the fan blade structure 1 rotates, not only the abovementioned effects can be achieved, but also the best stability can be achieved.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A fan blade structure, comprising an axle seat and plural vanes, wherein each vane is connected to the axle seat and includes a vane body, and the vane body is provided with an air pressure structure which is extended from the axle seat, and an aft flow structure which is extended from an end of the air pressure structure, with that the angle of air pressure structure is smaller than that of air flow structure.

2. The fan blade structure according to claim 1, wherein the air pressure structure is provided with a downward pressure surface, and the pressure surface is a curved structure.

3. The fan blade structure according to claim 1, wherein the air flow structure is provided with a downward wind surface, and the wind surface is a curved structure.

4. The fan blade structure according to claim 1, wherein the axle seat is provided with a horizontal plane, and a first angle is defined between the horizontal plane and the air pressure structure.

5. The fan blade structure according to claim 4, wherein a second angle is defined between the air flow structure and the horizontal plane, and the second angle is larger than the first angle.

6. The fan blade structure according to claim 1, wherein the air pressure structure and the air flow structure are a continuous curved structure.
